(19) United States
(12) Patent Application Publication
(10) Pub. No.: US 2022/0219669 A1
(43) Pub. Date: Jul. 14, 2022

(54) INFORMATION PROCESSING DEVICE AND PROGRAM

(71) Applicant: TOYOTA JIDOSHA KABUSHIKI KAISHA, Toyota-shi (JP)

(72) Inventors: Yuka SHIRAIWA, Fuji-shi (JP); Hirotaka SAITO, Sunto-gun (JP); Yuma MATSUMOTO, Susono-shi (JP); Takahiro UCHIDA, Susono-shi (JP); Shuji MORIYAMA, Susono-shi (JP)

(73) Assignee: TOYOTA JIDOSHA KABUSHIKI KAISHA, Toyota-shi (JP)

(21) Appl. No.: 17/540,937

(22) Filed: Dec. 2, 2021

(30) Foreign Application Priority Data
Jan. 13, 2021 (JP) 2021-003681

(51) Int. Cl. B60W 20/12; G01C 21/34; G01C 21/36; B60W 30/182; B60L 50/60

(52) U.S. Cl. CPC B60W 20/12; G01C 21/34; B60W 2555/20; B60W 30/182; B60L 50/60; G01C 21/3676

(57) ABSTRACT

An information processing device includes a processor including hardware. When a vehicle equipped with a battery that supplies electric power to a traction motor acquires disaster information indicating that occurrence of a predictable disaster is predicted around a current position while the vehicle is traveling, the processor sets an area that is reachable with a current state of charge of the battery and is a safe area for the disaster, guides the vehicle to the set area, and switches to an energy saving mode in which power consumption is smaller than a normal mode when the vehicle reaches the area.

### CROSS-REFERENCE TO RELATED APPLICATION

This application claims priority to Japanese Patent Application No. 2021-003681 filed on Jan. 13, 2021, incorporated herein by reference in its entirety.

### BACKGROUND

### 1. Technical Field

The present disclosure relates to an information processing device and a program.

### 2. Description of Related Art

With the spread of hybrid vehicles and electric vehicles, the number of vehicles equipped with batteries that can be charged from an external power source is increasing. In the event of a recent disaster, the amount of electric power required tends to increase. Therefore, it is known to utilize the electric power of a vehicle battery as an emergency power source.

Japanese Unexamined Patent Application Publication No. 2013-009488 (JP 2013-009488 A) discloses that, when an emergency disaster early warning is received by the home energy management system (HEMS), charging of the vehicle battery from the external power source is started under the control of the HEMS in order to secure the electric power of the vehicle battery.

### SUMMARY

In the configuration described in JP 2013-009488 A, the vehicle is required to be connected to the charging equipment. Therefore, there is room for improvement in how to secure the electric power of the vehicle battery for the case where the vehicle is not connected to the charging equipment, for example, while the vehicle is traveling.

The present disclosure has been made in view of the above circumstances, and it is an object of the present disclosure to provide an information processing device and a program capable of securing the electric power of the vehicle battery when occurrence of a disaster is predicted while the vehicle is traveling.

An information processing device according to the present disclosure includes a processor including hardware. The processor sets, when a vehicle equipped with a battery that supplies electric power to a traction motor acquires disaster information indicating that occurrence of a predictable disaster is predicted around a current position while the vehicle is traveling, an area that is reachable with a current state of charge of the battery and is a safe area for the disaster, guides the vehicle to the set area, and switches to an energy saving mode in which power consumption is smaller than a normal mode when the vehicle reaches the area.

A program according to the present disclosure causes a processor including hardware to: set, when a vehicle equipped with a battery that supplies electric power to a traction motor acquires disaster information indicating that occurrence of a predictable disaster is predicted around a current position while the vehicle is traveling, an area that is reachable with a current state of charge of the battery and is a safe area for the disaster; guide the vehicle to the set area; and switch to an energy saving mode in which power consumption is smaller than a normal mode when the vehicle reaches the area.

According to the present disclosure, the electric power of the vehicle battery can be secured when occurrence of a disaster is predicted while the vehicle is traveling.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic view showing a vehicle equipped with an information processing device according to the embodiment;

FIG. 2 is a block diagram showing a functional block of a vehicle;

FIG. 3 is a flowchart showing a processing flow of traveling control;

FIG. 4 is a flowchart showing a processing flow of mode control; and

FIG. 5 is a flowchart showing a processing flow of mode control in a modification.

### DETAILED DESCRIPTION OF EMBODIMENTS

Hereinafter, an information processing device and a program according to an embodiment of the present disclosure will be specifically described with reference to the drawings. Further, the present disclosure is not limited to the embodiment described below.

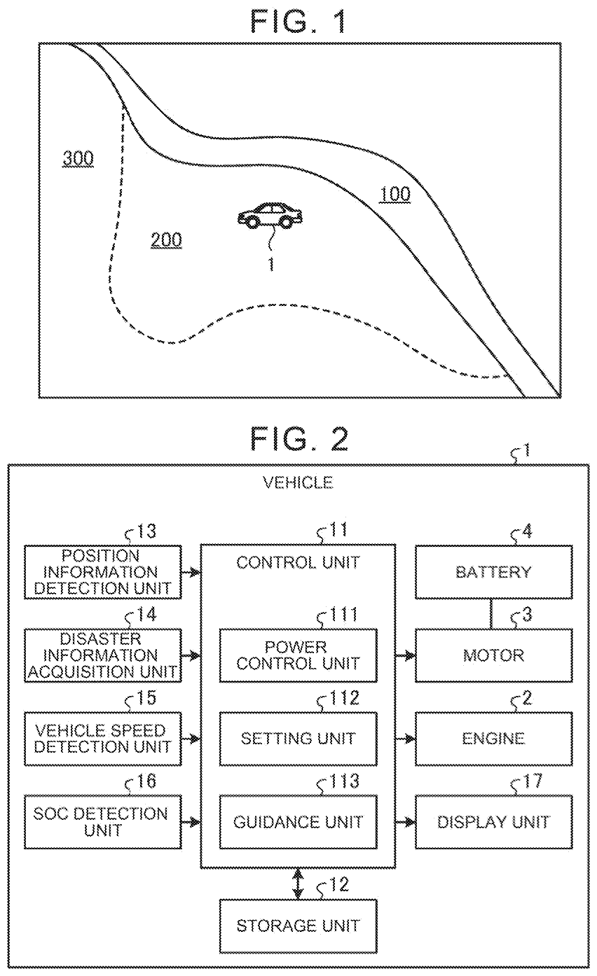

FIG. 1 is a schematic view showing a vehicle equipped with an information processing device according to the embodiment. A vehicle 1 is configured so as to be able to secure electric power of a vehicle battery when occurrence of a predictable disaster is predicted around a current position during traveling. For example, as shown in FIG. 1, when the vehicle 1 is traveling near a river 100 and is determined to be located in an area 200 where occurrence of a disaster is predicted, the vehicle 1 can move from the area 200 to a safe area 300 while securing the electric power of the vehicle battery. Note that, the broken line shown in FIG. 1 represents the boundary line between the area 200 where occurrence of a disaster is predicted and the area 300 that is a safe area for a disaster.

Examples of the predictable disasters include rain, wind, a typhoon, tsunami, and a tornado. In the case of a typhoon, it is possible to predict the time slot and area affected by the typhoon in advance based on typhoon course prediction information. Further, in the case of heavy rainfall, it is possible to predict the amount of precipitation in a specific area. Therefore, it is possible to predict an effect on the river 100 in accordance with precipitation caused by the typhoon or heavy rain. In this case, it is possible to acquire disaster information indicating that there is an increased risk of flooding from the embankment, collapse of the embankment, debris flow, etc. as a disaster of the river 100. The disaster information includes forecast information before an actual disaster (flooding, collapse, and debris flow) occurs. Another example of a disaster caused by rain is a landslide. It is also possible to acquire the disaster information indicating places where the risk of landslides has increased in accordance with the amount of precipitation caused by heavy rain.

Then, when a predictable disaster occurs, a power system may be cut off, such as the electric wire being cut off, and the supply of commercial power may be temporarily unavailable. Therefore, in the event of a disaster, it is possible to supply electric power externally of the vehicle 1 using the electric power of the vehicle battery mounted on the vehicle 1 as an emergency power source.

FIG. 2 is a block diagram showing a functional block of a vehicle. As shown in FIG. 2, the vehicle 1 includes an engine 2, a motor 3, a battery 4, a control unit 11, a storage unit 12, a position information detection unit 13, a disaster information acquisition unit 14, a vehicle speed detection unit 15, a state-of-charge (SOC) detection unit 16, and a display unit 17.

The vehicle 1 is a hybrid vehicle equipped with the engine 2 and the motor 3 as power sources and the battery 4 that stores electric power to be supplied to the motor 3. The engine 2 consumes fuel to generate electric power. The vehicle 1 can be refueled at a refueling point such as a gas station. Further, the vehicle 1 is a plug-in hybrid vehicle capable of charging the battery 4 with electric power supplied from an external power source.

The motor 3 is a traction motor, and is composed of a motor generator that functions as an electric motor and a generator. The motor 3 and the battery 4 are electrically connected via an inverter. When the motor 3 functions as a generator, the motor 3 can generate electric power using the power of the engine 2 or using an external force input from drive wheels (regenerative power generation). Then, the electric power generated by the motor 3 is stored in the battery 4.

The battery 4 is a storage battery that stores electric power to be supplied to the motor 3. For example, the battery 4 is composed of a secondary battery such as a lithium ion battery. Then, a charging cable of a charging stand is connected to a charging port of the vehicle 1 such that the electric power supplied from the external power source can be stored in the battery 4. Further, the electric power stored in the battery 4 can be supplied externally. That is, the battery 4 can be used as a power source to supply electric power to an electric device outside the vehicle. As described above, the place where the charging station is installed and the place where electric power is supplied externally of the vehicle serve as charging and discharging points.

The control unit 11 includes a processor and a memory. The processor includes a central processing unit (CPU), a digital signal processor (DSP), a field-programmable gate array (FPGA), and the like. The memory is a main storage device, and includes a random access memory (RAM), a read-only memory (ROM), or the like. The control unit 11 loads the program stored in the storage unit 12 into the work area of the memory (main storage device) and executes the program, and controls each component, etc. through the execution of the program such that the function that satisfies a predetermined purpose can be realized. That is, the control unit 11 is included in the information processing device mounted on the vehicle 1. In other words, the control unit 11 is included in an electronic control unit (ECU) that controls the vehicle 1.

The storage unit 12 is composed of a recording medium such as erasable programmable ROM (EPROM). The storage unit 12 stores various programs executed by the control unit 11. For example, the storage unit 12 stores a program for executing drive control for controlling a traveling mode of the vehicle 1.

The position information detection unit 13 is a sensor that detects a current position of the vehicle 1. For example, the position information detection unit 13 is composed of a positioning device that uses a global positioning system (GPS).

The disaster information acquisition unit 14 is a communication unit that acquires disaster information related to a predictable disaster. For example, the disaster information acquisition unit 14 acquires disaster information by wireless communication with an external server. The disaster information includes predictive information indicating that there is a high risk of a predictable disaster. Therefore, the disaster information includes severe weather terminology such as heavy rain warning, flood warning, and flood warning information.

The vehicle speed detection unit 15 is a sensor that detects the vehicle speed. The vehicle speed of the vehicle 1 is detected by the vehicle speed detection unit 15.

The SOC detection unit 16 is a sensor that detects the state of charge (SOC) of the battery 4. The SOC represents a charging state of the battery 4. The SOC detection unit 16 can detect the current SOC.

The display unit 17 is a display that displays various types of information. For example, a display included in a car navigation device can be mentioned. Further, the information controlled by the control unit 11 is displayed on the display unit 17.

Further, signals from the position information detection unit 13, the disaster information acquisition unit 14, the vehicle speed detection unit 15, and the SOC detection unit 16 are input to the control unit 11. Then, the control unit 11 executes various controls based on the input signal. The control unit 11 includes a power control unit 111, a setting unit 112, and a guidance unit 113.

The power control unit 111 executes power control that consumes the electric power of the battery 4. The control unit 11 can control the vehicle 1 in a plurality of traveling modes, and the power control unit 111 executes power control in accordance with the traveling modes. The traveling modes include a normal mode that is a normal traveling mode, an energy saving mode in which less power is consumed than the normal mode, a power consumption mode that prioritizes electric power consumption over fuel consumption, and a fuel consumption mode that prioritizes fuel consumption over electric power consumption. The control unit 11 can switch the traveling mode among the normal mode, the energy saving mode, the power consumption mode, and the fuel consumption mode.

For example, when the control unit 11 sets the normal mode, the power control unit 111 executes the power control to make the power consumption a normal amount. When the control unit 11 sets the energy saving mode, the power control unit 111 executes the power control to reduce the power consumption as compared with the normal mode. In the energy saving mode, control for suppressing the maximum speed and control for suppressing the maximum electric power are executed. Further, when the power consumption mode is set by the control unit 11, the power control unit 111 executes the power control in which the power consumption is larger than the fuel consumption. In the power consumption mode above, for example, the power control unit 111 executes control to consume the electric power of the battery 4 without consuming fuel. Further, when the fuel consumption mode is set by the control unit 11, the power control unit 111 executes the power control in which the fuel consumption is larger than the power consumption. In the fuel consumption mode above, for example, the power control unit 111 controls the motor 3 such that the motor 3 does not consume the electric power of the battery 4.

The setting unit 112 sets the area 200 where occurrence of a disaster is predicted, the area 300 that is a safe area for a disaster, a destination of the vehicle 1, and the like. For example, the setting unit 112 sets the area 200 where occurrence of a disaster is predicted and the area 300 that is a safe area for a disaster based on the disaster information input from the disaster information acquisition unit 14 to the control unit 11. When setting the area, the setting unit 112 can set the area using the map information stored in the storage unit 12. Further, the setting unit 112 can set a location selected by the user (driver, passenger) of the vehicle 1 as the destination based on the information related to the destination candidate displayed on the display unit 17. Then, the control unit 11 displays the area and the destination set by the setting unit 112 on the display unit 17.

The guidance unit 113 controls the planned traveling route of the vehicle 1. The guidance unit 113 executes guidance control for guiding the vehicle 1 toward the area 300 that is a safe area or the destination set by the setting unit 112. For example, when the area 200 where occurrence of a disaster is predicted and the area 300 that is a safe area are set based on the disaster information, the guidance unit 113 displays, on the display unit 17, the guidance information for guiding the traveling route from the current position to the area 300. With this configuration, the guidance unit 113 can guide the vehicle 1 to the area 300 that is a safe area. When the destination is set while the vehicle 1 is located in the area 300, the guidance unit 113 displays the guidance information for guiding the traveling route from the current position to the destination on the display unit 17. With this configuration, the guidance unit 113 can guide the vehicle 1 in the area 300 to the destination.

As described above, the control unit 11 executes traveling control and power control based on various types of input information. For example, the control unit 11 determines whether the vehicle 1 is traveling based on the input information from the vehicle speed detection unit 15. Then, the control unit 11 determines that the occurrence of a disaster is predicted and determines whether the current position during traveling is within the area where the occurrence of the disaster is predicted based on the input information from the position information detection unit 13 and the disaster information acquisition unit 14. Further, the control unit 11 sets an area that can be reached by the electric power of the battery 4 when the vehicle 1 travels in an electric vehicle (EV) traveling mode based on the input information from the SOC detection unit 16. That is, the control unit 11 calculates a cruising range in the EV traveling mode based on the current SOC of the battery 4, and sets the reachable area from the current position based on the calculated cruising range.

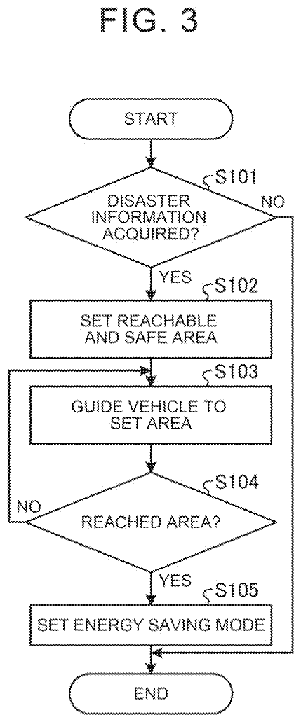

FIG. 3 is a flowchart showing a processing flow of traveling control. The control shown in FIG. 3 is executed by the control unit 11 while the vehicle 1 is traveling.

The control unit 11 determines whether the disaster information acquisition unit 14 acquires the disaster information indicating that the occurrence of a predictable disaster is predicted around the current position while the vehicle 1 is traveling (step S101). In step S101, the control unit 11 can determine whether occurrence of a predictable disaster is predicted around the current position based on the current position of the vehicle 1 and the disaster information. That is, in step S101, the control unit 11 determines whether the current position of the vehicle 1 is included in the area where the occurrence of a disaster is predicted.

When the vehicle 1 does not acquire the disaster information while traveling (step S101: No), the present control routine ends.

When the vehicle 1 acquires disaster information while traveling (step S101: Yes), the control unit 11 sets an area that can be reached with the current SOC of the battery 4 and is a safe area for the disaster (step S102). In step S102, the control unit 11 sets an area that is a safe area for the area 200 where the occurrence of a disaster is predicted based on the disaster information and that the vehicle 1 can reach when the vehicle 1 travels in the EV traveling mode while consuming the electric power of the battery 4.

For example, as shown in FIG. 1, the information related to the area 200 where the occurrence of a disaster is predicted is set based on, for example, a hazard map published by a local government. The storage unit 12 stores the hazard map information. In step S102, the control unit 11 refers to the storage unit 12 and sets an area where the occurrence of a disaster is predicted based on the hazard map information. In this case, the control unit 11 sets the area outside the area where the occurrence of a disaster is predicted as a safe area. Then, the control unit 11 determines whether the vehicle 1 can reach the area that is a safe area with the current SOC. At that time, the control unit 11 calculates the distance that the vehicle 1 can travel in the EV traveling mode (that is, the cruising range) based on the current SOC detected by the SOC detection unit 16. The control unit 11 determines whether the vehicle 1 can reach the safe area in the EV traveling mode based on the calculated cruising range and the current position of the vehicle 1. When the control unit 11 determines that the vehicle 1 can reach the area in the EV traveling mode, the control unit 11 sets the area as the area 300 that is reachable and safe.

When the control unit 11 sets the area 300 that is reachable and safe, the control unit 11 guides the vehicle 1 to the set area 300 (step S103). In step S103, information for guiding the route from the current position to the set area 300 is displayed on the display unit 17.

Then, the control unit 11 determines whether the vehicle 1 has reached the area 300 set as the reachable and safe area (step S104). In step S104, it is determined whether the vehicle 1 has reached the area 300 based on the information indicating the current position of the vehicle 1 and the information of the set area.

When the vehicle 1 has not reached the area 300 set as a reachable and safe area (step S104: No), the present control routine returns to step S103.

When the vehicle 1 reaches the area 300 set as the reachable and safe area (step S104: Yes), the control unit 11 sets the vehicle 1 to the energy saving mode in which less power is consumed than the normal mode (step S105). In step S105, the traveling mode is switched from the normal mode to the energy saving mode. When the process in step S105 is executed, the present control routine ends.

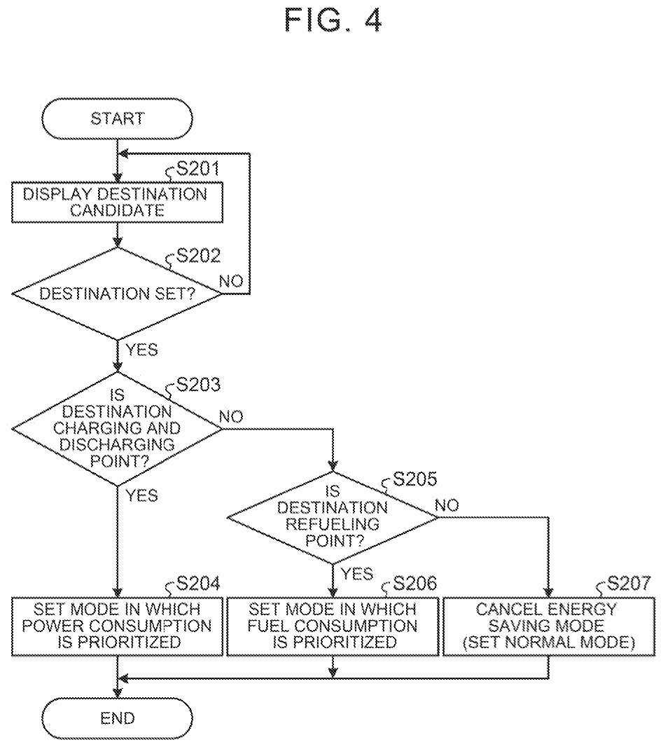

FIG. 4 is a flowchart showing a processing flow of mode control. The control shown in FIG. 4 is executed by the control unit 11 in a state where the vehicle 1 is located in the area 300, the destination is not set, and the traveling mode is set to the energy saving mode.

The control unit 11 displays the candidate destinations present in the area 300 on the display unit 17 in a state where the vehicle 1 is located in the area 300 set as the reachable and safe area and the traveling mode is set to the energy saving mode (step S201). Examples of the destinations include a charging and discharging point, a refueling point, and an evacuation site. In step S201, information on at least one of the charging and discharging point, the refueling point, and the evacuation site is displayed on the display unit 17 as a destination candidate (candidate point). That is, the process in step S201 is executed when the destination in the area 300 is not set. As an example, the process in step S201 is executed at the timing when the vehicle 1 enters the area (the area 300 that is a safe area) from outside the area (the area where the occurrence of a disaster is predicted).

Further, in step S201, the control unit 11 can display the candidate point closest to the current position on the display unit 17 for each type of destination. For example, when displaying the charging and discharging point, the control unit 11 displays, on the display unit 17, the charging and discharging point closest to the current position among a plurality of the charging and discharging points. When displaying the refueling point, the control unit 11 displays, on the display unit 17, the refueling point closest to the current position among a plurality of the refueling points. When displaying the evacuation site, the control unit 11 displays the evacuation site closest to the current position among a plurality of the evacuation sites as a candidate point on the display unit 17. As described above, the control unit 11 can display the closest charging and discharging point, the closest refueling point, and the closest evacuation site as the candidate points for three points. Further, in step S201, only the destination of the type specified by the user can be displayed. For example, when the user specifies the charging and discharging point, the control unit 11 does not include the refueling point or the evacuation site in the candidate points, and displays only the candidate points for the charging and discharging point on the display unit 17.

The control unit 11 determines whether any of the candidate points is set as the destination (step S202). In step S202, the control unit 11 determines whether any of the points of the candidate point information displayed as the destination candidates is set as the destination. The control unit 11 sets the location as the destination when the candidate point information displayed on the display unit 17 is selected by the user.

When none of the candidate points is set as the destination (step S202: No), the present control routine returns to step S201.

When any of the candidate points is set as the destination (step S202: Yes), the control unit 11 determines whether the set destination is the charging and discharging point (step S203).

When the set destination is the charging and discharging point (step S203: Yes), the control unit 11 sets the power consumption mode in which power consumption is prioritized over fuel consumption (step S204). In step S204, the energy saving mode is switched to the power consumption mode. This is because the charging and discharging point is set as the reachable destination such that, when the vehicle 1 reaches the destination, the battery 4 can be charged with the electric power from the external power source. That is, even when the vehicle 1 travels in the EV traveling mode and consumes the electric power to reach the destination, it is expected that the consumed electric power is charged at the destination. Therefore, for the vehicle 1 after reaching at the destination, it is more beneficial to leave the fuel rather than the electric power so as to secure the cruising range thereafter. Therefore, power consumption is prioritized by the process in step S204. When the process in step S204 is executed, the present control routine ends.

When the set destination is not the charging and discharging point (step S203: No), the control unit 11 determines whether the set destination is the refueling point (step S205).

When the set destination is the refueling point (step S205: Yes), the control unit 11 sets the fuel consumption mode in which fuel consumption is prioritized over power consumption (step S206). In step S206, the energy saving mode is switched to the fuel consumption mode. This is because the refueling point is set as the reachable destination such that, when the vehicle 1 reaches the destination, the vehicle 1 can be refueled at a gas station or the like. That is, even when the vehicle 1 travels in an engine traveling mode and consumes fuel to reach the destination, it is expected that the consumed fuel is refueled at the destination. Therefore, for the vehicle 1 after reaching at the destination, it is more beneficial to secure the electric power rather than the fuel so as to secure the cruising range thereafter. Therefore, fuel consumption is prioritized by the process in step S206. When the process in step S206 is executed, the present control routine ends.

When the set destination is not the refueling point (step S205: No), the control unit 11 determines that the evacuation site is set as the destination, and cancels the energy saving mode (step S207). In step S207, the energy saving mode is switched to the normal mode. When a negative determination is made in step S203 and a negative determination is made in step S205, the control unit 11 determines that the set destination is the evacuation site. When the process in step S207 is executed, the present control routine ends.

As described above, according to the embodiment, when the vehicle 1 acquires the disaster information related a predictable disaster while traveling, the vehicle 1 can reach the area 300 that is a safe area while securing the electric power of the battery 4. With this configuration, the electric power of the battery 4 can be secured as much as possible before a disaster occurs while avoiding the disaster.

When executing the power control to consume the electric power of the battery 4, the control unit 11 can execute control to suppress power consumption of an auxiliary machine, in addition to a case of suppressing power consumption of the motor 3. That is, when the control unit 11 suppresses the SOC decrease of the battery 4, the control unit 11 can execute the power control that reduces the power consumption of the auxiliary machine.

Further, when guiding the vehicle 1 to the area 300 or the destination, the control unit 11 can provide a voice guidance using a speaker in addition to a guidance using the display unit 17. That is, the guidance unit 113 provides guidance by voice or image display. Then, when the vehicle 1 can move to a safe evacuation site, the control unit 11 can also provide a guidance to the user to refrain from driving operations that consume more electric power such as acceleration.

Further, the control unit 11 cancels the energy saving mode when the set destination is a location where at least two of the charging and discharging point, the refueling point, and the evacuation site overlap with each other. For example, in the process in step S201, the control unit 11 displays a location where at least two of the charging and discharging point, the refueling point, and the evacuation site overlap with each other as the destination candidate. Specifically, examples of the above include the case where the charging and discharging point and the refueling point are the same location, the case where the charging and discharging point and the evacuation site are the same location, and the case where the charging and discharging point, the refueling point, and the evacuation site are the same location. Then, in the determination process in step S203, the control unit 11 determines whether the set destination is a location where at least two of the charging and discharging point, the refueling point, and the evacuation site overlap with each other.

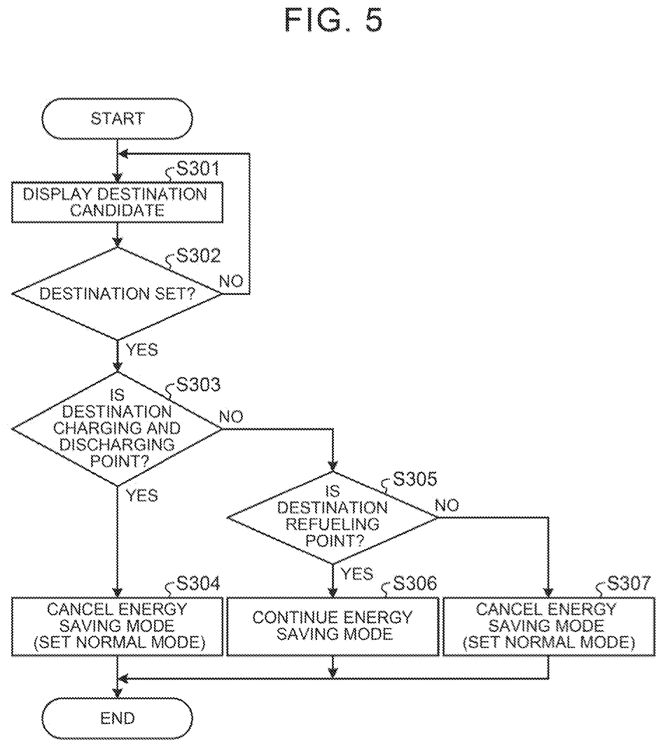

Further, the vehicle 1 is not limited to the hybrid vehicle. That is, the vehicle 1 may be any vehicle that is equipped with the battery 4 for supplying electric power to the traction motor and can receive supply of the electric power from the external power source. Therefore, the vehicle 1 may be an electric vehicle that does not include the engine 2. Therefore, as a modification of the embodiment, an example of the mode control when the vehicle 1 is an electric vehicle is illustrated in FIG. 5.

FIG. 5 is a flowchart showing a processing flow of mode control in a modification. The control shown in FIG. 5 is executed by the control unit 11 in a state where the vehicle 1 that is an electric vehicle is located in the area 300, the destination is not set, and the traveling mode is set to the energy saving mode. Note that, steps S301 to S303 and S305 shown in FIG. 5 are the same as steps S201 to S203 and S205 shown in FIG. 4. Therefore, description thereof will be omitted.

As shown in FIG. 5, when the set destination is the charging and discharging point (step S303: Yes), the control unit 11 cancels the energy saving mode (step S304). In step S304, the energy saving mode is switched to the normal mode. This is because the charging and discharging point is set as the reachable destination such that, when the vehicle 1 reaches the destination, the battery 4 can be charged with the electric power from the external power source. That is, even when the vehicle 1 travels in the EV traveling mode and the electric power is consumed to reach the destination, it is expected that the consumed electric power is charged at the destination. When the process in step S304 is executed, the present control routine ends.

Further, when the set destination is the refueling point (step S305: Yes), the control unit 11 continues the energy saving mode (step S306). When the process in step S306 is executed, this control routine ends.

When the set destination is not the refueling point (step S305: No), the control unit 11 determines that the evacuation site has been set as the destination, and cancels the energy saving mode (step S307). In step S307, the energy saving mode is switched to the normal mode. When a negative determination is made in step S303 and a negative determination is made in step S305, the control unit 11 determines that the set destination is the evacuation site. When the process in step S307 is executed, the present control routine ends.

Further, even when the vehicle 1 is an electric vehicle, the control unit 11 cancels the energy saving mode when the set destination is a place where at least two of the charging and discharging point, the refueling point, and the evacuation site overlap with each other.

Further effects and modifications can be easily derived by those skilled in the art. The broader aspects of the present disclosure are not limited to the particular details and representative embodiments shown and described above. Accordingly, various modifications may be made without departing from the spirit or scope of the general inventive concept as defined by the appended claims and their equivalents.

What is claimed is:

1. An information processing device, comprising a processor including hardware, wherein
the processor:
sets, when a vehicle equipped with a battery that supplies electric power to a traction motor acquires disaster information indicating that occurrence of a predictable disaster is predicted around a current position while the vehicle is traveling, an area that is reachable with a current state of charge of the battery and is a safe area for the disaster;
guides the vehicle to the set area; and
switches to an energy saving mode in which power consumption is smaller than a normal mode when the vehicle reaches the area.

2. The information processing device according to claim 1, further comprising a display, wherein when the vehicle is located in the area, the processor displays at least one of information on a charging and discharging point, a refueling point, and an evacuation site on the display as a destination candidate.

3. The information processing device according to claim 2, wherein the processor sets a candidate selected by a user from the destination candidate displayed on the display as a destination.

4. The information processing device according to claim 3, wherein when the charging and discharging point is set as the destination, the processor sets a mode in which power consumption is prioritized over fuel consumption in the case where the vehicle is a hybrid vehicle.

5. The information processing device according to claim 3, wherein when the refueling point is set as the destination, the processor sets a mode in which fuel consumption is prioritized over power consumption in the case where the vehicle is a hybrid vehicle.

6. The information processing device according to claim 3, wherein when the evacuation site is set as the destination, the processor cancels the energy saving mode in the case where the vehicle is a hybrid vehicle.

7. The information processing device according to claim 4, wherein when the set destination is a place where at least two of the charging and discharging point, the refueling point, and the evacuation site overlap with each other, the processor cancels the energy saving mode in the case where the vehicle is the hybrid vehicle.

8. The information processing device according to claim 3, wherein when the charging and discharging point is set as the destination, the processor cancels the energy saving mode in the case where the vehicle is an electric vehicle.

9. The information processing device according to claim 3, wherein when the refueling point is set as the destination, the processor continues the energy saving mode in the case where the vehicle is an electric vehicle.

10. The information processing device according to claim 3, wherein when the evacuation site is set as the destination, the processor cancels the energy saving mode in the case where the vehicle is an electric vehicle.

11. The information processing device according to claim 8, wherein when the set destination is a place where at least two of the charging and discharging point, the refueling point, and the evacuation site overlap with each other, the processor cancels the energy saving mode in the case where the vehicle is the electric vehicle.

12. A program that causes a processor including hardware to:
set, when a vehicle equipped with a battery that supplies electric power to a traction motor acquires disaster information indicating that occurrence of a predictable disaster is predicted around a current position while the vehicle is traveling, an area that is reachable with a current state of charge of the battery and is a safe area for the disaster;
guide the vehicle to the set area; and
switch to an energy saving mode in which power consumption is smaller than a normal mode when the vehicle reaches the area.

13. The program according to claim 12, causing the processor to display, when the vehicle is located in the area, at least one of information on a charging and discharging point, a refueling point, and an evacuation site on a display as a destination candidate.

14. The program according to claim 13, causing the processor to set a candidate selected by a user from the destination candidate displayed on the display as a destination.

15. The program according to claim 14, causing the processor to set, when the charging and discharging point is set as the destination, a mode in which power consumption is prioritized over fuel consumption in the case where the vehicle is a hybrid vehicle.

16. The program according to claim 14, causing the processor to set, when the refueling point is set as the destination, a mode in which fuel consumption is prioritized over power consumption in the case where the vehicle is a hybrid vehicle.

17. The program according to claim 14, causing the processor to cancel, when the evacuation site is set as the destination, the energy saving mode in the case where the vehicle is a hybrid vehicle.

18. The program according to claim 15, causing the processor to cancel, when the set destination is a place where at least two of the charging and discharging point, the refueling point, and the evacuation site overlap with each other, the energy saving mode in the case where the vehicle is the hybrid vehicle.

19. The program according to claim 14, causing the processor to cancel, when the charging and discharging point is set as the destination, the energy saving mode in the case where the vehicle is an electric vehicle.

20. The program according to claim 14, causing the processor to continue, when the refueling point is set as the destination, the energy saving mode in the case where the vehicle is an electric vehicle.
